(19) United States
(12) Patent Application Publication
(10) Pub. No.: US 2024/0178209 A1
(43) Pub. Date: May 30, 2024

(54) Display Device Including Oxide Semiconductor

(71) Applicant: LG Display Co., Ltd., Seoul (KR)

(72) Inventors: Ki Tae Kim, Paju-si (KR); Deuk Ho Yeon, Paju-si (KR); Sun Wook Ko, Paju-si (KR)

(21) Appl. No.: 18/465,707

(22) Filed: Sep. 12, 2023

(30) Foreign Application Priority Data
Nov. 28, 2022 (KR) 10-2022-0161351

(51) Int. Cl. H01L 25/16; H01L 25/075; H01L 29/786; H01L 33/62

(52) U.S. Cl. CPC H01L 25/167; H01L 25/0753; H01L 29/7869; H01L 29/78696; H01L 33/62

(57) ABSTRACT

Disclosed is a display device including an oxide semiconductor. The display device includes a light-emitting device and a pixel driving circuit located in each pixel area. The pixel driving circuit supplies a driving current corresponding to a data signal to the light-emitting device in response to a gate signal. The pixel driving circuit includes a driving thin-film transistor and at least one switching thin-film transistor. The driving thin-film transistor includes a driving semiconductor pattern made of an oxide semiconductor. A conductive pattern including a metal is located under the driving semiconductor pattern. The conductive pattern is in contact with the driving semiconductor pattern. The conductive pattern has a larger work function than the driving semiconductor pattern. Accordingly, occurrence of mura at low grayscale is prevented without a reduction in on-current. Consequently, the display device exhibits improved image quality.

### CROSS-REFERENCE TO RELATED APPLICATION

This application claims the benefit of Korean Patent Application No. 10-2022-0161351, filed on Nov. 28, 2022, which is hereby incorporated by reference as if fully set forth herein.

### BACKGROUND OF THE INVENTION

### Field of the Invention

The present disclosure relates to a display device in which a driving semiconductor pattern in each pixel area is made of an oxide semiconductor.

### Discussion of the Related Art

In general, a display device may provide an image to a user. For example, such a display device may include a plurality of pixel areas. A light-emitting device and a pixel driving circuit may be located in each pixel area. The light-emitting device may emit light having a specific color. For example, the light-emitting device may include an emission layer, which is located between a first electrode and a second electrode.

The pixel driving circuit may supply a driving current corresponding to a data signal to the light-emitting device in response to a gate signal. For example, the pixel driving circuit may include a driving thin-film transistor and at least one switching thin-film transistor. The driving thin-film transistor may generate the driving current corresponding to the data signal. For example, the driving thin-film transistor may include a driving semiconductor pattern, a driving gate electrode, a driving source electrode, and a driving drain electrode.

The driving semiconductor pattern may have electrical conductivity corresponding to a voltage applied to the driving gate electrode. The driving semiconductor pattern may include a semiconductor material. For example, the driving semiconductor pattern may be made of an oxide semiconductor. However, in the driving thin-film transistor including the driving semiconductor pattern made of an oxide semiconductor, the amount of change in the driving current due to change in the voltage applied to the driving gate electrode may be increased. Accordingly, mura may occur in a low grayscale region in the display device.

When a separation distance between the driving semiconductor pattern and the driving gate electrode of the driving thin-film transistor is increased, the amount of change in the driving current due to change in the voltage applied to the driving gate electrode may be reduced. However, in the display device, the on-current of the driving thin-film transistor may decrease. Accordingly, in the display device, the electrical characteristics of the driving thin-film transistor may be degraded. Therefore, the overall brightness and image quality of the display device may be degraded.

### SUMMARY OF THE INVENTION

Accordingly, the present disclosure is directed to a display device including an oxide semiconductor that substantially obviates one or more problems due to limitations and disadvantages of the related art.

An object of the present disclosure is to provide a display device capable of preventing occurrence of mura at low grayscale without deterioration in the brightness thereof.

Another object of the present disclosure is to provide a display device capable of increasing an S-factor of a driving thin-film transistor without changing a separation distance between a driving semiconductor pattern and a driving gate electrode.

However, the objects to be accomplished by the present disclosure are not limited to the above-mentioned objects, and other objects not mentioned herein will be clearly understood by those skilled in the art from the following description.

Additional advantages, objects, and features of the disclosure will be set forth in part in the description which follows and in part will become apparent to those having ordinary skill in the art upon examination of the following or may be learned from practice of the disclosure. The objects and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a display device includes a device substrate. A pixel driving circuit and a light-emitting device are located on the device substrate. The pixel driving circuit includes a driving thin-film transistor. The driving thin-film transistor includes a driving semiconductor pattern. The driving semiconductor pattern is made of an oxide semiconductor. The light-emitting device is electrically connected to the pixel driving circuit. A conductive pattern is located between the device substrate and the driving semiconductor pattern. The driving semiconductor pattern is in contact with the upper surface of the conductive pattern that is opposite the device substrate. The conductive pattern includes a metal. The conductive pattern has a larger work function than the driving semiconductor pattern.

The lower end portion of the driving semiconductor pattern that is located close to the conductive pattern may include a depletion region.

The conductive pattern may be electrically connected to a driving source electrode of the driving thin-film transistor.

The conductive pattern may include a region located outside the driving semiconductor pattern. The driving source electrode may be in contact with the conductive pattern at a position outside the driving semiconductor pattern.

The conductive pattern may include a first pattern layer and a second pattern layer. The second pattern layer may be located on the first pattern layer. The driving semiconductor pattern may be in contact with the second pattern layer. The second pattern layer may have a larger work function than the driving semiconductor pattern.

The second pattern layer may be made of a conductive metal oxide.

The second pattern layer may include the same metal as the first pattern layer.

The conductive pattern may include one of copper, molybdenum, nickel, cobalt, and platinum.

The conductive pattern may overlap a portion of the driving semiconductor pattern. The driving semiconductor pattern may include a channel region located on the conductive pattern.

In another aspect of the present disclosure, a display device includes a device substrate. A first conductive pattern, an upper buffer layer, and a pixel driving circuit are located on the device substrate. The upper buffer layer covers the first conductive pattern. A second conductive pattern and a light-emitting device are located on the upper buffer layer. The second conductive pattern includes a metal. The pixel driving circuit includes a first thin-film transistor and a second thin-film transistor. The first thin-film transistor is located on the first conductive pattern. The second thin-film transistor is located on the second conductive pattern. The light-emitting device is electrically connected to the pixel driving circuit. The second thin-film transistor includes a semiconductor pattern made of an oxide semiconductor. The semiconductor pattern of the second thin-film transistor is in Schottky contact with the second conductive pattern.

The second conductive pattern may be electrically connected to a source electrode of the second thin-film transistor.

The first thin-film transistor may include a semiconductor pattern located on the same layer as the second conductive pattern.

The semiconductor pattern of the first thin-film

transistor may include the same material as the semiconductor pattern of the second thin-film transistor.

An upper gate insulating layer may be located on the upper buffer layer. The upper gate insulating layer may cover the semiconductor pattern of the first thin-film transistor and the semiconductor pattern of the second thin-film transistor. Each of the first thin-film transistor and the second thin-film transistor may include a gate electrode located on the upper gate insulating layer. The gate electrode of the first thin-film transistor may be located on the same layer as the gate electrode of the second thin-film transistor.

In still another aspect of the present disclosure, a thin film transistor for driving a light-emitting element of a display device comprises an oxide semiconductor pattern including oxide semiconductor material; a gate insulation layer disposed on a first side of the oxide semiconductor pattern; a gate electrode disposed on the gate insulation layer; a first electrode electrically connected to the oxide semiconductor pattern; a second electrode electrically connected to the oxide semiconductor pattern, the second electrode electrically connected to the light-emitting element such that the thin film transistor drives current through the light-emitting element; a conductive pattern disposed directly on and in contact with a second side of the oxide semiconductor pattern, the conductive pattern having a first work function greater than a second work function of the oxide semiconductor pattern.

The conductive pattern is electrically coupled to a DC voltage or the second electrode.

The oxide semiconductor pattern includes a source region, a drain region, and a channel region between the source region and the drain region, the source region and the drain region including the oxide semiconductor material doped with a dopant, and the channel region including the oxide semiconductor material free of the dopant, the conductive pattern extends shorter than edges of the oxide semiconductor region, and the conductive pattern overlaps with the channel region but does not overlap with the source region or the drain region.

In some embodiments, the conductive pattern extends shorter than edges of the oxide semiconductor region; and the oxide semiconductor region has stepped shapes. In other embodiments, the conductive pattern overlaps with the entire oxide semiconductor pattern and extends beyond edges of the oxide semiconductor pattern.

In some embodiments, the thin film transistor may further comprise another conductive pattern disposed beyond edges of the oxide semiconductor pattern, the source electrode electrically connected to the another conductive pattern.

In some embodiments, the conductive pattern comprises a first conductive pattern layer and a second conductive pattern layer disposed on the first conductive pattern layer, the oxide semiconductor pattern is in direct contact with the second conductive pattern layer, and the second conductive pattern layer has the first work function greater than the second work function of the oxide semiconductor pattern. The second conductive pattern layer may comprise a conductive metal oxide. The conductive pattern may comprise one of copper, molybdenum, nickel, cobalt, and platinum.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment (s) of the disclosure and together with the description serve to explain the principle of the disclosure. In the drawings:

FIG. 1 is a view schematically showing a display device according to an embodiment of the present disclosure;

FIG. 2 is a view showing a circuit in a unit pixel area in the display device according to the embodiment of the present disclosure;

FIG. 3 is a view showing a cross-section taken along line I-I′ in FIG. 1 and a cross-section obtained by cutting a portion of the unit pixel area;

FIG. 4 is an enlarged view of a region indicated by “K” in FIG. 3;

FIG. 5 is a work function graph for explaining a depletion region between the second semiconductor pattern and the second conductive pattern; and

FIGS. 6 to 12 are views showing display devices according to other embodiments of the present disclosure.

### DETAILED DESCRIPTION OF THE INVENTION

The details of the above objects, technical configurations, and effects of the present disclosure will be clearly understood from the following detailed description taken in conjunction with the accompanying drawings showing embodiments of the present disclosure. Although exemplary embodiments of the present disclosure will be described, it will be apparent that the technical spirit of the present disclosure can be practiced by those skilled in the art without being restricted or limited to the embodiments.

Further, throughout the specification, the same reference numerals represent the same components, and in the drawings, the length and thickness of layers or areas may be exaggerated for the sake of convenience. In addition, when a first element is referred to as being “on” a second element, it can be directly on the second element or be indirectly on the second element with a third element interposed therebetween.

It will be understood that the terms “first” and “second” are used herein to describe various elements and are only used to distinguish one element from another element. Thus, a first element may be termed a second element, and similarly, a second element may be termed a first element without departing from the teachings of the present disclosure.

Terms used in the following description are used only to describe the specific embodiments and are not intended to restrict the present disclosure. The expression of singularity includes a plural meaning unless the singularity expression is explicitly different in context. In the specification, the terms “comprising, ” “including,” and “having” shall be understood to designate the presence of particular features, numbers, steps, operations, elements, parts, or combinations thereof but not to preclude the presence or addition of one or more other features, numbers, steps, operations, elements, parts, or combinations thereof.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

### Embodiment

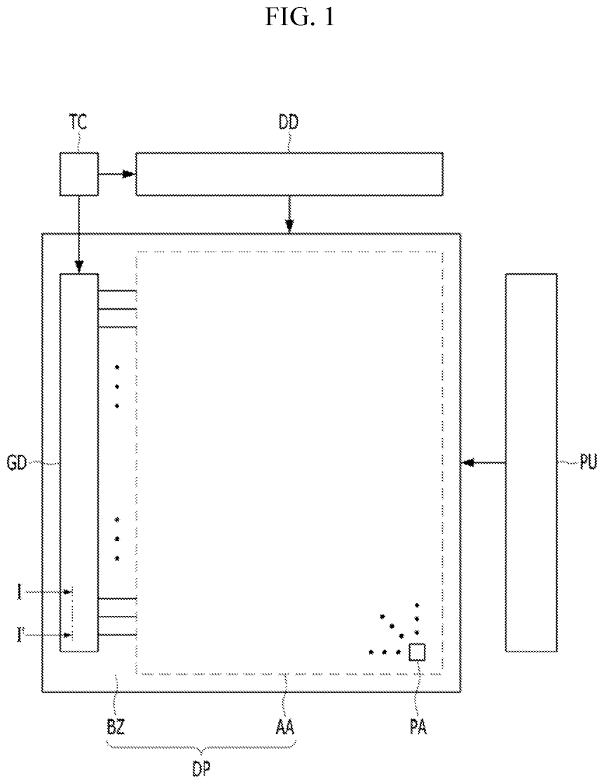

FIG. 1 is a view schematically showing a display device according to an embodiment of the present disclosure, and

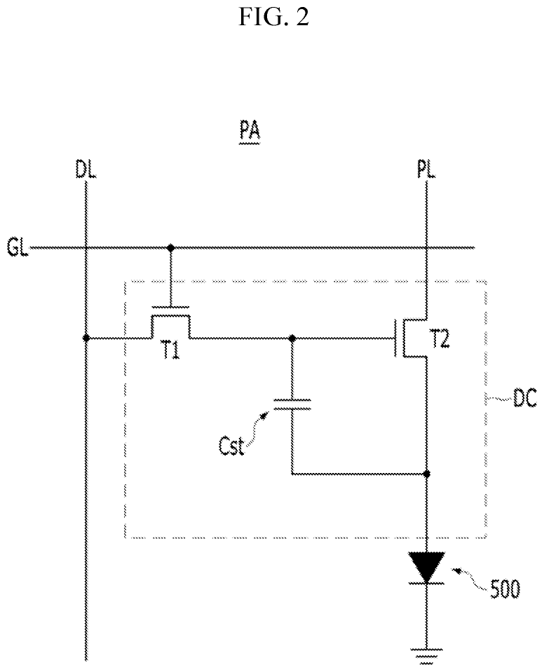

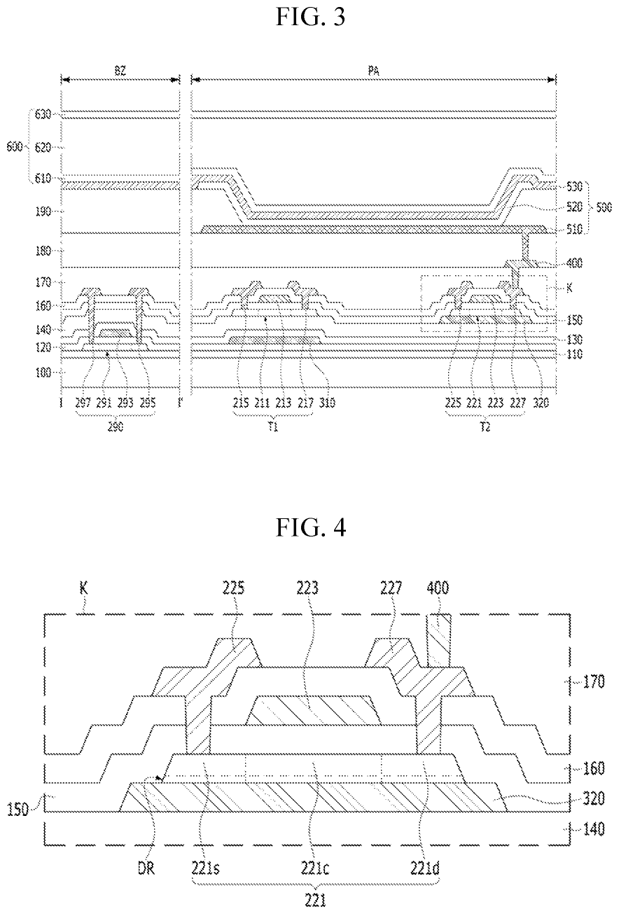

FIG. 2 is a view showing a circuit in a unit pixel area in the display device according to the embodiment of the present disclosure. FIG. 3 is a view showing a cross-section taken along line I-I′ in FIG. 1 and a cross-section obtained by cutting a portion of the unit pixel area. FIG. 4 is an enlarged view of a region indicated by “K” in FIG. 3.

Referring to FIGS. 1 to 4, a display device according to an embodiment of the present disclosure may include a display panel DP. The display panel DP may generate an image to be provided to a user. For example, the display panel DP may include a plurality of pixel areas PA.

Various signals may be supplied to the respective pixel areas PA through signal lines GL, DL, and PL. For example, the signal lines GL, DL, and PL may include gate lines GL for application of gate signals to the respective pixel areas PA, data lines DL for application of data signals to the respective pixel areas PA, and power voltage supply lines PL for application of positive supply voltages VDD to the respective pixel areas PA. The gate lines GL may be electrically connected to a gate driver GD. The data lines DL may be electrically connected to a data driver DD. The power voltage supply lines PL may be electrically connected to a power unit PU.

The gate driver GD and the data driver DD may be controlled by a timing controller TC. For example, the gate driver GD may receive clock signals, reset signals, and a start signal from the timing controller TC, and the data driver DD may receive digital video data and a source timing signal from the timing controller TC.

Each pixel area PA may realize a specific color. For example, a light-emitting device 500 and a pixel driving circuit DC electrically connected to the light-emitting device 500 may be located in each pixel area PA. The light-emitting device 500 and the pixel driving circuit DC in each pixel area PA may be located on a device substrate 100. The device substrate 100 may include an insulating material. For example, the device substrate 100 may include glass or plastic.

The light-emitting device 500 may emit light having a specific color. For example, the light-emitting device 500 may include a first electrode 510, an emission layer 520, and a second electrode 530, which are sequentially stacked on the device substrate 100.

The first electrode 510 may include a conductive material. The first electrode 510 may include a material having a high reflectance. For example, the first electrode 510 may include a metal such as aluminum (Al) or silver (Ag). The first electrode 510 may have a multilayer structure. For example, the first electrode 510 may have a structure in which a reflective electrode made of a metal is located between transparent electrodes made of a transparent conductive material such as indium tin oxide (ITO) or indium zinc oxide (IZO).

The emission layer 520 may generate light having brightness corresponding to a voltage difference between the first electrode 510 and the second electrode 530. For example, the emission layer 520 may include an emission material layer (EML) including an emission material. The emission material may include an organic material, an inorganic material, or a hybrid material. For example, the display device according to the embodiment of the present disclosure may be an organic light-emitting display device including an organic emission material.

The emission layer 520 may have a multilayer structure. For example, the emission layer 520 may further include at least one of a hole injection layer (HIL), a hole transport layer (HTL), an electron transport layer (ETL), or an electron injection layer (EIL). Accordingly, in the display device according to the embodiment of the present disclosure, the luminous efficiency of the emission layer 520 may be improved.

The second electrode 530 may include a conductive material. The second electrode 530 may include a material different from that of the first electrode 510. The transmittance of the second electrode 530 may be greater than the transmittance of the first electrode 510. For example, the second electrode 530 may be a transparent electrode made of a transparent conductive material such as ITO or IZO. Accordingly, in the display device according to the embodiment of the present disclosure, light generated by the emission layer 520 may be emitted to the outside through the second electrode 530.

The pixel driving circuit DC may supply a driving current corresponding to the data signal to the light-emitting device 500 during one frame in response to the gate signal. For example, the pixel driving circuit DC may include a first thin-film transistor T1, a second thin-film transistor T2, and a storage capacitor Cst.

The first thin-film transistor T1 may include a first semiconductor pattern 211, a first gate electrode 213, a first drain electrode 215, and a first source electrode 217. The first thin-film transistor T1 may transmit the data signal to a second gate electrode 223 of the second thin-film transistor T2 in response to the gate signal. For example, the first thin-film transistor T1 may be a switching thin-film transistor. The first gate electrode 213 may be electrically connected to the gate line GL, and the first drain electrode 215 may be electrically connected to the data line DL.

The first semiconductor pattern 211 may include a semiconductor material. For example, the first semiconductor pattern 211 may include an oxide semiconductor such as indium gallium zinc oxide (IGZO). The first semiconductor pattern 211 may include a first source region, a first channel region, and a first drain region. The first channel region may be located between the first source region and the first drain region. The resistance of the first source region and the resistance of the first drain region may be lower than the resistance of the first channel region. For example, each of the first source region and the first drain region may include a conductorized region of an oxide semiconductor. The first channel region may be a non-conductorized region of an oxide semiconductor.

The first gate electrode 213 may include a conductive material. For example, the first gate electrode 213 may include a metal such as aluminum (Al), chromium (Cr), copper (Cu), molybdenum (Mo), titanium (Ti), or tungsten (W). The first gate electrode 213 may be located on the first semiconductor pattern 211. For example, the first gate electrode 213 may overlap the first channel region of the first semiconductor pattern 211. The first source region and the first drain region of the first semiconductor pattern 211 may be located outside the first gate electrode 213. The first gate electrode 213 may be electrically insulated from the first semiconductor pattern 211. For example, the first source region of the first semiconductor pattern 211 may be electrically connected to the first drain region of the first semiconductor pattern 211 in response to the gate signal.

The first drain electrode 215 may include a conductive material. For example, the first drain electrode 215 may include a metal such as aluminum (Al), chromium (Cr), copper (Cu), molybdenum (Mo), titanium (Ti), or tungsten (W). The first drain electrode 215 may include a material different from that of the first gate electrode 213. The first drain electrode 215 may be located on a different layer from the first gate electrode 213. For example, the first drain electrode 215 may be electrically insulated from the first gate electrode 213. The first drain electrode 215 may be electrically connected to the first drain region of the first semiconductor pattern 211.

The first source electrode 217 may include a conductive material. For example, the first source electrode 217 may include a metal such as aluminum (Al), chromium (Cr), copper (Cu), molybdenum (Mo), titanium (Ti), or tungsten (W). The first source electrode 217 may include a material different from that of the first gate electrode 213. The first source electrode 217 may be located on a different layer from the first gate electrode 213. For example, the first source electrode 217 may be located on the same layer as the first drain electrode 215. The first source electrode 217 may include the same material as the first drain electrode 215. The first source electrode 217 may be electrically insulated from the first gate electrode 213. For example, the first source electrode 217 may be electrically connected to the first source region of the first semiconductor pattern 211.

The second thin-film transistor T2 may include a second semiconductor pattern 221, a second gate electrode 223, a second drain electrode 225, and a second source electrode 227. The second thin-film transistor T2 may generate the driving current corresponding to the data signal. For example, the second thin-film transistor T2 may be a driving thin-film transistor. The second gate electrode 223 may be electrically connected to the first source electrode 217, and the second drain electrode 225 may be electrically connected to the power voltage supply line PL. The light-emitting device 500 may be electrically connected to the second thin-film transistor T2. For example, the second source electrode 227 may be electrically connected to the first electrode 510 of the light-emitting device 500.

The second semiconductor pattern 221 may include a semiconductor material. For example, the second semiconductor pattern 221 may include an oxide semiconductor such as IGZO. The second semiconductor pattern 221 may include a second channel region located between a second source region and a second drain region. The second channel region may have a higher resistance than the second source region and the second drain region. For example, each of the second source region and the second drain region may include a conductorized region of an oxide semiconductor, and the second channel region may be a non-conductorized region of an oxide semiconductor.

The second semiconductor pattern 221 may include the same material as the first semiconductor pattern 211. For example, the second semiconductor pattern 221 may be formed simultaneously with formation of the first semiconductor pattern 211. The second source region and the second drain region of the second semiconductor pattern 221 may have the same resistance as the first source region and the first drain region of the first semiconductor pattern 211. For example, the resistance of the second channel region may be equal to that of the first channel region.

The second gate electrode 223 may include a conductive material. For example, the second gate electrode 223 may include a metal such as aluminum (Al), chromium (Cr), copper (Cu), molybdenum (Mo), titanium (Ti), or tungsten (W). The second gate electrode 223 may include the same material as the first gate electrode 213. The second gate electrode 223 may be located on the same layer as the first gate electrode 213. For example, the second gate electrode 223 may be formed simultaneously with formation of the first gate electrode 213.

The second gate electrode 223 may be located on the second semiconductor pattern 221. For example, the second gate electrode 223 may overlap the second channel region of the second semiconductor pattern 221. The second source region and the second drain region of the second semiconductor pattern 221 may be located outside the second gate electrode 223. The second gate electrode 223 may be electrically insulated from the second semiconductor pattern 221. For example, the second channel region of the second semiconductor pattern 221 may have electrical conductivity corresponding to a voltage applied to the second gate electrode 223.

The second drain electrode 225 may include a conductive material. For example, the second drain electrode 225 may include a metal such as aluminum (Al), chromium (Cr), copper (Cu), molybdenum (Mo), titanium (Ti), or tungsten (W). The second drain electrode 225 may include a material different from that of the second gate electrode 223. The second drain electrode 225 may be located on a different layer from the second gate electrode 223. For example, the second drain electrode 225 may be electrically insulated from the second gate electrode 223. The second drain electrode 225 may be electrically connected to the second drain region of the second semiconductor pattern 221.

The second drain electrode 225 may be located on the same layer as the first drain electrode 215. The second drain electrode 225 may include the same material as the first drain electrode 215. For example, the second drain electrode 225 may be formed simultaneously with formation of the first drain electrode 215. Accordingly, the display device according to the embodiment of the present disclosure may exhibit improved process efficiency.

The second source electrode 227 may include a conductive material. For example, the second source electrode 227 may include a metal such as aluminum (Al), chromium (Cr), copper (Cu), molybdenum (Mo), titanium (Ti), or tungsten (W). The second source electrode 227 may include a material different from that of the second gate electrode 223. The second source electrode 227 may be located on a different layer from the second gate electrode 223. For example, the second source electrode 227 may be electrically insulated from the second gate electrode 223. The second source electrode 227 may be electrically connected to the second source region of the second semiconductor pattern 221.

The second source electrode 227 may be located on the same layer as the first source electrode 217. The second source electrode 227 may include the same material as the first source electrode 217. For example, the second source electrode 227 may be formed simultaneously with formation of the first source electrode 217. Accordingly, the display device according to the embodiment of the present disclosure may exhibit improved process efficiency.

The storage capacitor Cst may maintain a signal applied to the second gate electrode 223 of the second thin-film transistor T2 during one frame. For example, the storage capacitor Cst may be electrically connected between the second gate electrode 223 and the second source electrode 227 of the second thin-film transistor T2. The storage capacitor Cst may have a structure in which capacitor electrodes are stacked one above another. The storage capacitor Cst may be formed using a process of forming the first thin-film transistor T1 and the second thin-film transistor T2. For example, the storage capacitor Cst may include a first capacitor electrode located on the same layer as the second gate electrode 223 and a second capacitor electrode located on the same layer as the second source electrode 227. Accordingly, the display device according to the embodiment of the present disclosure may exhibit improved process efficiency.

The display panel DP may include an active area AA in which the pixel areas PA are located and a bezel area BZ located outside the active area AA. At least one of the gate driver GD, the data driver DD, the power unit PU, or the timing controller TC may be located in the bezel area BZ of the display panel DP. For example, the display device according to the embodiment of the present disclosure may be a gate-in-panel (GIP) type display device in which the gate driver GD is formed in the bezel area BZ of the display panel DP. The gate driver GD may include at least one circuit thin-film transistor 290.

The circuit thin-film transistor 290 may be located in the bezel area BZ of the device substrate 100. The circuit thin-film transistor 290 may have the same structure as the first thin-film transistor T1 or the second thin-film transistor T2 located in each pixel area PA. For example, the circuit thin-film transistor 290 may include a circuit semiconductor pattern 291, a circuit gate electrode 293, a circuit drain electrode 295, and a circuit source electrode 297.

The circuit semiconductor pattern 291 may include a semiconductor material. The circuit semiconductor pattern 291 may include a material different from those of the first semiconductor pattern 211 and the second semiconductor pattern 221 in each pixel area PA. For example, the circuit semiconductor pattern 291 may include low-temperature poly-Si (LTPS). The circuit semiconductor pattern 291 may be located on a different layer from the first semiconductor pattern 211 and the second semiconductor pattern 221 in each pixel area PA. For example, the circuit semiconductor pattern 291 may have different electrical characteristics from the first semiconductor pattern 211 and the second semiconductor pattern 221 in each pixel area PA.

The circuit semiconductor pattern 291 may include a circuit source region, a circuit channel region, and a circuit drain region. The circuit channel region may be located between the circuit source region and the circuit drain region. The resistance of the circuit source region and the resistance of the circuit drain region may be lower than the resistance of the circuit channel region. For example, the circuit source region and the circuit drain region may include conductive impurities. The circuit channel region may be a region not doped with conductive impurities.

The circuit gate electrode 293 may include a conductive material. For example, the circuit gate electrode 293 may include a metal such as aluminum (Al), chromium (Cr), copper (Cu), molybdenum (Mo), titanium (Ti), or tungsten (W). The circuit gate electrode 293 may be located on the circuit semiconductor pattern 291. For example, the circuit gate electrode 293 may overlap the circuit channel region of the circuit semiconductor pattern 291. The circuit source region and the circuit drain region of the circuit semiconductor pattern 291 may be located outside the circuit gate electrode 293. The circuit gate electrode 293 may be electrically insulated from the circuit semiconductor pattern 291. For example, the circuit source region of the circuit semiconductor pattern 291 may be electrically connected to the circuit drain region of the circuit semiconductor pattern 291 in response to a corresponding signal.

The circuit gate electrode 293 may be located on a different layer from the first gate electrode 213 and the second gate electrode 223 in each pixel area PA. For example, the circuit gate electrode 293 may include a material different from those of the first gate electrode 213 and the second gate electrode 223 in each pixel area PA.

The circuit drain electrode 295 may include a conductive material. For example, the circuit drain electrode 295 may include a metal such as aluminum (Al), chromium (Cr), copper (Cu), molybdenum (Mo), titanium (Ti), or tungsten (W). The circuit drain electrode 295 may include a material different from that of the circuit gate electrode 293. The circuit drain electrode 295 may be located on a different layer from the circuit gate electrode 293. For example, the circuit drain electrode 295 may be electrically insulated from the circuit gate electrode 293. The circuit drain electrode 295 may be electrically connected to the circuit drain region of the circuit semiconductor pattern 291.

The circuit drain electrode 295 may be located on the same layer as the first drain electrode 215 and the second drain electrode 225 in each pixel area PA. The circuit drain electrode 295 may include the same material as the first drain electrode 215 and the second drain electrode 225 in each pixel area PA. For example, the circuit drain electrode 295 may be formed simultaneously with formation of the first drain electrode 215 and the second drain electrode 225 in each pixel area PA. Accordingly, the display device according to the embodiment of the present disclosure may exhibit improved process efficiency.

The circuit source electrode 297 may include a conductive material. For example, the circuit source electrode 297 may include a metal such as aluminum (Al), chromium (Cr), copper (Cu), molybdenum (Mo), titanium (Ti), or tungsten (W). The circuit source electrode 297 may include a material different from that of the circuit gate electrode 293. The circuit source electrode 297 may be located on a different layer from the circuit gate electrode 293. For example, the circuit source electrode 297 may be located on the same layer as the circuit drain electrode 295. The circuit source electrode 297 may include the same material as the circuit drain electrode 295. The circuit source electrode 297 may be electrically insulated from the circuit gate electrode 293. For example, the circuit source electrode 297 may be electrically connected to the circuit source region of the circuit semiconductor pattern 291.

The circuit source electrode 297 may be located on the same layer as the first source electrode 217 and the second source electrode 227 in each pixel area PA. The circuit source electrode 297 may include the same material as the first source electrode 217 and the second source electrode 227 in each pixel area PA. For example, the circuit source electrode 297 may be formed simultaneously with formation of the first source electrode 217 and the second source electrode 227 in each pixel area PA. Accordingly, the display device according to the embodiment of the present disclosure may exhibit improved process efficiency.

A plurality of insulating layers 110, 120, 130, 140, 150, 160, 170, 180, and 190 may be located on the device substrate 100 to prevent unnecessary electrical connection in each pixel area PA. For example, a lower buffer layer 110, a lower gate insulating layer 120, a lower interlayer insulating layer 130, an upper buffer layer 140, an upper gate insulating layer 150, an upper interlayer insulating layer 160, a first planarization layer 170, a second planarization layer 180, and a bank insulating layer 190 may be located on the device substrate 100.

The lower buffer layer 110 may be located close to the device substrate 100. The lower buffer layer 110 may prevent contamination by the device substrate 100 in a process of forming the pixel driving circuit DC in each pixel area PA and the circuit thin-film transistor 290. For example, the lower buffer layer 110 may completely cover the active area AA and the bezel area BZ of the device substrate 100. The pixel driving circuit DC in each pixel area PA and the circuit thin-film transistor 290 may be located on the lower buffer layer 110. The lower buffer layer 110 may include an insulating material. For example, the lower buffer layer 110 may include silicon oxide (SiOx) and silicon nitride (SiNx). The lower buffer layer 110 may have a multilayer structure. For example, the lower buffer layer 110 may have a structure in which an inorganic insulating layer made of silicon oxide (SiOx) and an inorganic insulating layer made of silicon nitride (SiNx) are stacked one above another.

The lower gate insulating layer 120 may electrically insulate the circuit semiconductor pattern 291 of the circuit thin-film transistor 290 from the circuit gate electrode 293 of the circuit thin-film transistor 290. For example, the circuit semiconductor pattern 291 may be located between the lower buffer layer 110 and the lower gate insulating layer 120. The lower gate insulating layer 120 may cover the circuit semiconductor pattern 291. The lower gate insulating layer 120 may include an insulating material. For example, the lower gate insulating layer 120 may include silicon oxide (SiOx). The lower gate insulating layer 120 may extend to the active area AA of the device substrate 100. For example, the first thin-film transistor T1 and the second thin-film transistor T2 in each pixel area PA may be located on the lower gate insulating layer 120.

The lower interlayer insulating layer 130 may electrically insulate the circuit drain electrode 295 and the circuit source electrode 297 from the circuit gate electrode 291. For example, the circuit drain electrode 295 and the circuit source electrode 297 may be located on the lower interlayer insulating layer 130. The circuit gate electrode 291 may be located between the lower gate insulating layer 120 and the lower interlayer insulating layer 130. The lower interlayer insulating layer 130 may include an insulating material. For example, the lower interlayer insulating layer 130 may include silicon nitride (SiNx). Accordingly, in the display device according to the embodiment of the present disclosure, the electrical characteristics of the circuit semiconductor pattern 291 may be stabilized due to hydrogen contained in the lower interlayer insulating layer 130.

The lower interlayer insulating layer 130 may extend to the active area AA of the device substrate 100. For example, the first thin-film transistor T1 and the second thin-film transistor T2 in each pixel area PA may be located on the lower interlayer insulating layer 130. A first conductive pattern 310 may be located between the lower gate insulating layer 120 and the lower interlayer insulating layer 130 in each pixel area PA. The first conductive pattern 310 may include a conductive material. For example, the first conductive pattern 310 may include the same material as the circuit gate electrode 293. The first conductive pattern 310 may be formed simultaneously with formation of the circuit gate electrode 293. For example, the first conductive pattern 310 may be located on the same layer as the circuit gate electrode 293.

The first conductive pattern 310 in each pixel area PA may overlap the first thin-film transistor T1 in the corresponding pixel area PA. For example, the first thin-film transistor T1 in each pixel area PA may be located on the first conductive pattern 310 in the corresponding pixel area PA. Accordingly, in the display device according to the embodiment of the present disclosure, external light traveling toward the first semiconductor pattern 211 in each pixel area PA after passing through the device substrate 100 may be blocked by the first conductive pattern 310 in the corresponding pixel area PA. For example, the first conductive pattern 310 in each pixel area PA may have a larger size than the first semiconductor pattern 211 in the corresponding pixel area PA. Therefore, in the display device according to the embodiment of the present disclosure, a change in the characteristics of the first thin-film transistor T1 located in each pixel area PA due to external light may be prevented without deterioration in process efficiency.

The upper buffer layer 140 may be located between the lower interlayer insulating layer 130 and the first semiconductor pattern 211 in each pixel area PA. The upper buffer layer 140 may include an insulating material. The upper buffer layer 140 may include a material having a relatively low hydrogen content. For example, the upper buffer layer 140 may be an inorganic insulating layer made of silicon oxide (SiOx). Accordingly, in the display device according to the embodiment of the present disclosure, movement of the hydrogen contained in the lower interlayer insulating layer 130 toward the first semiconductor pattern 211 in each pixel area PA may be blocked by the upper buffer layer 140. That is, in the display device according to the embodiment of the present disclosure, a change in the characteristics of the first semiconductor pattern 211 located in each pixel area PA due to diffusion of hydrogen may be prevented. For example, the upper buffer layer 140 may have a greater thickness than the lower interlayer insulating layer 130. Therefore, in the display device according to the embodiment of the present disclosure, deterioration in the characteristics of the pixel driving circuit DC located in each pixel area PA due to hydrogen may be prevented.

The upper buffer layer 140 may extend beyond the first semiconductor pattern 211 located in each pixel area PA. For example, the second thin-film transistor T2 in each pixel area PA may be located on the upper buffer layer 140. Accordingly, in the display device according to the embodiment of the present disclosure, a change in the characteristics of the second thin-film transistor T2 located in each pixel area PA due to diffusion of hydrogen may be prevented. The circuit drain electrode 295 and the circuit source electrode 297 may be located on the upper buffer layer 140.

The upper gate insulating layer 150 may electrically insulate the first semiconductor pattern 211 from the first gate electrode 213 in each pixel area PA. For example, the first semiconductor pattern 211 in each pixel area PA may be located between the upper buffer layer 140 and the upper gate insulating layer 150. The upper gate insulating layer 150 may cover the first semiconductor pattern 211 in each pixel area PA. The upper gate insulating layer 150 may include an insulating material. For example, the upper gate insulating layer 150 may be an inorganic insulating layer made of silicon oxide (SiOx). The upper gate insulating layer 150 may extend to the bezel area BZ of the device substrate 100. For example, the circuit drain electrode 295 and the circuit source electrode 297 may be located on the upper gate insulating layer 150 in the bezel area BZ.

The second semiconductor pattern 221 and the second gate electrode 223 in each pixel area PA may be electrically insulated by the upper gate insulating layer 150. For example, the upper gate insulating layer 150 may extend between the second semiconductor pattern 221 and the second gate electrode 223 in each pixel area PA. The separation distance between the second semiconductor pattern 221 and the second gate electrode 223 located in each pixel area PA may be equal to the separation distance between the first semiconductor pattern 211 and the first gate electrode 213 located in the corresponding pixel area PA. For example, the upper gate insulating layer 150 may be in contact with the first semiconductor pattern 211, the second semiconductor pattern 221, the first gate electrode 213, and the second gate electrode 223 in each pixel area PA. Accordingly, in the display device according to the embodiment of the present disclosure, a process of forming the pixel driving circuit DC located in each pixel area PA may be simplified.

The upper interlayer insulating layer 160 may electrically insulate the first drain electrode 215 and the first source electrode 217 in each pixel area PA from the first gate electrode 213 in the corresponding pixel area PA. The second drain electrode 225 and the second source electrode 227 in each pixel area PA may be electrically insulated from the second gate electrode 223 in the corresponding pixel area PA by the upper interlayer insulating layer 160. For example, the first drain electrode 215, the first source electrode 217, the second drain electrode 225, and the second source electrode 227 in each pixel area PA may be located on the upper interlayer insulating layer 160. The first drain electrode 215 and the first source electrode 217 in each pixel area PA may pass through the upper gate insulating layer 150 and the upper interlayer insulating layer 160 to be electrically connected to the first semiconductor pattern 211 in the corresponding pixel area PA. The second drain electrode 225 and the second source electrode 227 in each pixel area PA may pass through the upper gate insulating layer 150 and the upper interlayer insulating layer 160 to be electrically connected to the second semiconductor pattern 221 in the corresponding pixel area PA. The upper interlayer insulating layer 160 may include an insulating material. The upper interlayer insulating layer 160 may include a material different from that of the lower interlayer insulating layer 130. The upper interlayer insulating layer 160 may include a material having a relatively low hydrogen content. For example, the upper interlayer insulating layer 160 may be an inorganic insulating layer made of silicon oxide (SiOx). Accordingly, in the display device according to the embodiment of the present disclosure, a change in the characteristics of the first thin-film transistor T1 and the second thin-film transistor T2 located in each pixel area PA due to hydrogen may be prevented.

The upper interlayer insulating layer 160 may extend to the bezel area BZ of the device substrate 100. For example, the circuit drain electrode 295 and the circuit source electrode 297 may be located on the upper interlayer insulating layer 160. The circuit drain electrode 295 and the circuit source electrode 297 may be electrically connected to the circuit semiconductor pattern 291 through the lower gate insulating layer 120, the lower interlayer insulating layer 130, the upper buffer layer 140, the upper gate insulating layer 150, and the upper interlayer insulating layer 160.

The first planarization layer 170 may be located on the upper interlayer insulating layer 160. For example, the drain electrodes 215 and 225 and the source electrodes 217 and 227 in each pixel area PA may be covered by the first planarization layer 170. The circuit drain electrode 295 and the circuit source electrode 297 may be located between the upper interlayer insulating and layer 160 the first planarization layer 170. The second planarization layer 180 may be located on the first planarization layer 170. The first planarization layer 170 and the second planarization layer 180 may remove a step difference caused by the pixel driving circuit DC and the circuit thin-film transistor 290 in each pixel area PA. For example, the upper surface of the second planarization layer 180 that is opposite the device substrate 100 may be a flat surface.

Each of the first planarization layer 170 and the second planarization layer 180 may include an insulating material. Each of the first planarization layer 170 and the second planarization layer 180 may include a material different from that of the upper interlayer insulating layer 160. For example, each of the first planarization layer 170 and the second planarization layer 180 may be an organic insulating layer including an organic insulating material. The second planarization layer 180 may include the same material as the first planarization layer 170. The second planarization layer 180 may be in direct contact with the upper surface of the first planarization layer 170 that is opposite the device substrate 100. For example, the first planarization layer 170 and the second planarization layer 180 may be physically connected to each other. An interface between the first planarization layer 170 and the second planarization layer 180 may be invisible.

The light-emitting device 500 in each pixel area PA may be located on the second planarization layer 180. For example, the first electrode 510, the emission layer 520, and the second electrode 530 in each pixel area PA may be sequentially stacked on the second planarization layer 180 located in the corresponding pixel area PA. The first electrode 510 in each pixel area PA may be in direct contact with the upper surface of the second planarization layer 180. Accordingly, in the display device according to the embodiment of the present disclosure, a brightness difference depending on the generation position of light emitted from each light-emitting device 500 may be prevented.

Intermediate electrodes 400 may be located between the first planarization layer 170 and the second planarization layer 180. The intermediate electrodes 400 may include a conductive material. For example, the intermediate electrodes 400 may include a metal such as aluminum (Al), chromium (Cr), copper (Cu), molybdenum (Mo), titanium (Ti), or tungsten (W). The first electrode 510 in each pixel area PA may be electrically connected to the second source electrode 227 in the corresponding pixel area PA via one of the intermediate electrodes 400. For example, each of the intermediate electrodes 400 may pass through the first planarization layer 170 in each pixel area PA and may be in direct contact with the second source electrode 227 in the corresponding pixel area PA, and the first electrode 510 in each pixel area PA may pass through the second planarization layer 180 in the corresponding pixel area PA and may be in direct contact with one of the intermediate electrodes 400.

The bank insulating layer 190 may be located on the second planarization layer 180. The bank insulating layer 190 may define an emission area within each pixel area PA. For example, the bank insulating layer 190 may cover an edge of the first electrode 510 located in each pixel area PA. The emission layer 520 and the second electrode 530 in each pixel area PA may be sequentially stacked on the portion of the first electrode 510 that is exposed by the bank insulating layer 190. The bank insulating layer 190 may include an insulating material. For example, the bank insulating layer 190 may be an organic insulating layer including an organic insulating material. The bank insulating layer 190 may include a material different from that of the second planarization layer 180.

Light emitted from the light-emitting device 500 in each pixel area PA may have a different color from light emitted from the light-emitting device 500 in an adjacent pixel area PA. For example, the emission layer 520 in each pixel area PA may be spaced apart from the emission layer 520 in an adjacent pixel area PA. The emission layer 520 located in each pixel area PA may include an end portion located on the bank insulating layer 190. The emission layer 520 in each pixel area PA may be individually formed. For example, the emission layer 520 in each pixel area PA may be formed using a fine metal mask (FMM). A spacer may be located on the bank insulating layer 190. The spacer may prevent damage to the bank insulating layer 190 and the emission layer 520 due to the fine metal mask. The spacer may include an insulating material. For example, the spacer may include an organic insulating material. The spacer may include the same material as the bank insulating layer 190. For example, the bank insulating layer 190 and the spacer may be simultaneously formed through a patterning process using a halftone mask. An end portion of the emission layer 520 located in each pixel area PA may be spaced apart from the spacer.

A voltage applied to the second electrode 530 in each pixel area PA may be the same as a voltage applied to the second electrode 530 in an adjacent pixel area PA. For example, a negative supply voltage VSS may be applied to the second electrode 530 in each pixel area PA. The second electrode 530 in each pixel area PA may be electrically connected to the second electrode 530 in an adjacent pixel area PA. The second electrode 530 in each pixel area PA may include the same material as the second electrode 530 in an adjacent pixel area PA. For example, the second electrode 530 in each pixel area PA may be formed simultaneously with formation of the second electrode 530 in an adjacent pixel area PA. The second electrode 530 in each pixel area PA may be in direct contact with the second electrode 530 in an adjacent pixel area PA. For example, the second electrode 530 in each pixel area PA may extend onto the bank insulating layer 190. The bank insulating layer 190 may be covered by the second electrode 530. Accordingly, in the display device according to the embodiment of the present disclosure, a process of forming the second electrode 530 in each pixel area PA may be simplified. In addition, in the display device according to the embodiment of the present disclosure, the brightness of the light emitted from the light-emitting device 500 in each pixel area PA may be adjusted in response to the data signal applied to the pixel driving circuit DC in the corresponding pixel area PA.

An encapsulation unit 600 may be located on the light-emitting device 500 in each pixel area PA. The encapsulation unit 600 may prevent damage to the light-emitting devices 500 due to external moisture and impact. The encapsulation unit 600 may include a multilayer structure. For example, the encapsulation unit 600 may include a first encapsulation layer 610, a second encapsulation layer 620, and a third encapsulation layer 630, which are sequentially stacked one above another. Each of the first encapsulation 610, the second encapsulation layer 620, and the third encapsulation layer 630 may include an insulating material. The second encapsulation layer 620 may include a material different from those of the first encapsulation layer 610 and the third encapsulation layer 630. For example, the first encapsulation layer 610 and the third encapsulation layer 630 may be inorganic insulating layers made of silicon nitride (SiNx) or silicon oxide (SiOx), and the second encapsulation layer 620 may be an organic insulating layer made of an organic insulating material. Accordingly, in the display device according to the embodiment of the present disclosure, damage to the light-emitting devices 500 due to external moisture and impact may be effectively prevented.

A second conductive pattern 320 may be located between the upper buffer layer 140 and the second semiconductor pattern 221 in each pixel area PA. The second conductive pattern 320 may be in direct contact with the second semiconductor pattern 221. For example, the lower surface of the second semiconductor pattern 221 that faces the device substrate 100 may be in direct contact with the second conductive pattern 320. The second conductive pattern 320 may include a metal. Accordingly, in the display device according to the embodiment of the present disclosure, external light toward traveling the second semiconductor pattern 221 in each pixel area PA after passing through the device substrate 100 may be blocked by the second conductive pattern 320 in the corresponding pixel area PA. For example, the second conductive pattern 320 in each pixel area PA may have a larger size than the second semiconductor pattern 221 in the corresponding pixel area PA.

A work function of the second conductive pattern 320 may be greater than that of the second semiconductor pattern 221. For example, the second semiconductor pattern 221 may include IGZO having a work function of 4.0 eV, and the second conductive pattern 320 may include one of copper (Cu), molybdenum (Mo), nickel (Ni), cobalt (Co), and platinum (Pt) having a work function of 4.5 eV or more. A constant voltage may be applied to the second conductive pattern 320. For example, the second conductive pattern 320 may be electrically connected to a signal line supplying the negative supply voltage VSS.

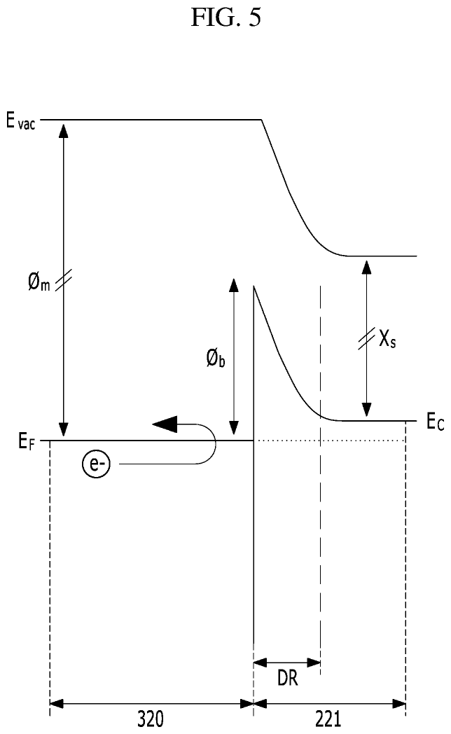

FIG. 5 is a work function graph for explaining a depletion region DR between the second semiconductor pattern 221 and the second conductive pattern 320. As shown in FIGS. 4 and 5, the second semiconductor pattern 221 may be in Schottky contact with the second conductive pattern 320. That is, electrons of a rear portion of the second semiconductor pattern 221 that is located close to the second conductive pattern 320 may be diffused to the second conductive pattern 320 due to a Fermi-level difference between the second conductive pattern 320 and the second semiconductor pattern 221, and a depletion region DR may be formed on the rear portion of the second semiconductor pattern 221 that is located close to the second conductive pattern 320. In FIG. 5, Evac is an energy level of electron in vacuum, EF is an energy level of electron in metal, Ec is an energy level of electron in semiconductor, Xs is an electron affinity, Φm is a work function in metal, and Φb=Φm−Xs.

Since electrons of the rear portion of the semiconductor pattern 221 are diffused into the second conductive pattern 320, the depletion region DR may mean a region in which electrons are not located. That is, parasitic capacitance due to the depletion region DR may be formed between the second conductive pattern 320 and the second semiconductor pattern 221. The amount of change in the effective gate voltage of the second thin-film transistor T2 located in each pixel area PA may be determined by the following equation. Here, ΔV_{eff} represents the amount of change in the effective gate voltage, ΔV_{GAT} represents the amount of change in the voltage applied to the second gate electrode 223 in the corresponding pixel area PA, C1 represents capacitance of the parasitic capacitor formed between the second conductive pattern 320 and the second semiconductor pattern 221 in the corresponding pixel area PA, C2 represents capacitance of the parasitic capacitor formed between the second semiconductor pattern 221 and the second gate electrode 223 in the corresponding pixel area PA, and C_{ACT} represents capacitance of the parasitic capacitor formed by the voltage applied to the second source region and the second drain region of the second semiconductor pattern 221 located in the corresponding pixel area PA.

$$Δ {V}_{eff} = \frac{C 2}{C 2 + {C}_{ACT} + C 1} \times Δ {V}_{GAT} \qquad [ Equation ]$$

Capacitance of a capacitor is inversely proportional to the distance between conductors constituting the corresponding capacitor. That is, C1 may be inversely proportional to the width of the depletion region DR formed in the corresponding pixel area PA, and C2 may be inversely proportional to the thickness of the upper gate insulating layer 150 located in the corresponding pixel area PA. The width of the depletion region DR formed by Schottky contact may be much smaller than the thickness of the upper gate insulating layer 150 formed through a deposition process. That is, in the display device according to the embodiment of the present disclosure, the parasitic capacitor formed between the second conductive pattern 320 and the second semiconductor pattern 221 in each pixel area PA has much larger capacitance than the parasitic capacitor formed between the second semiconductor pattern 221 and the second gate electrode 223 in the corresponding pixel area PA, and accordingly, the amount of change in the effective gate voltage of the second thin-film transistor T2 located in each pixel area PA may be reduced. In general, when the amount of change in an effective gate voltage of a thin-film transistor is reduced, an S-factor, which indicates an inverse ratio of a current change according to a change in voltage applied to a gate electrode of the corresponding thin-film transistor, is increased. Accordingly, in the display device according to the embodiment of the present disclosure, variation in the driving current depending on the voltage applied to the second gate electrode 223 of the second thin-film transistor T2 located in each pixel area PA may be reduced. Therefore, in the display device according to the embodiment of the present disclosure, occurrence of mura at low grayscale may be prevented.

In addition, in the display device according to the embodiment of the present disclosure, the S-factor of the second thin-film transistor T2 located in each pixel area PA may be increased without an increase in the thickness of the upper gate insulating layer 160 located in the corresponding pixel area PA. Accordingly, in the display device according to the embodiment of the present disclosure, occurrence of mura at low grayscale may be prevented without a reduction in the on-current of the second thin-film transistor T2 located in each pixel area PA. Therefore, in the display device according to the embodiment of the present disclosure, low-power driving may be realized, whereby power consumption may be reduced.

As a result, the display device according to the embodiment of the present disclosure may include the light-emitting device 500 and the pixel driving circuit DC, which are located in each pixel area PA. The pixel driving circuit DC includes the second thin-film transistor T2 which is electrically connected to the light-emitting device 500 and functions as a driving thin-film transistor. The second conductive pattern 320 located under the second thin-film transistor T2 may be in direct contact with the second semiconductor pattern 221 of the second thin-film transistor T2, which includes an oxide semiconductor, and the negative supply voltage VSS may be applied to the second conductive pattern 320, which includes a metal having a larger work function than that of the second semiconductor pattern 221. Accordingly, in the display device according to the embodiment of the present disclosure, the lower end portion of the second semiconductor pattern 221 that is located close to the second conductive pattern 320 in each pixel area PA may include the depletion region DR, whereby the S-factor of the second thin-film transistor T2 may be increased without an increase in the thickness of the upper gate insulating layer 150. Therefore, in the display device according to the embodiment of the present disclosure, reduction in the on-current of the second thin-film transistor T2 located in each pixel area PA may be prevented, and occurrence of mura at low grayscale may be prevented.

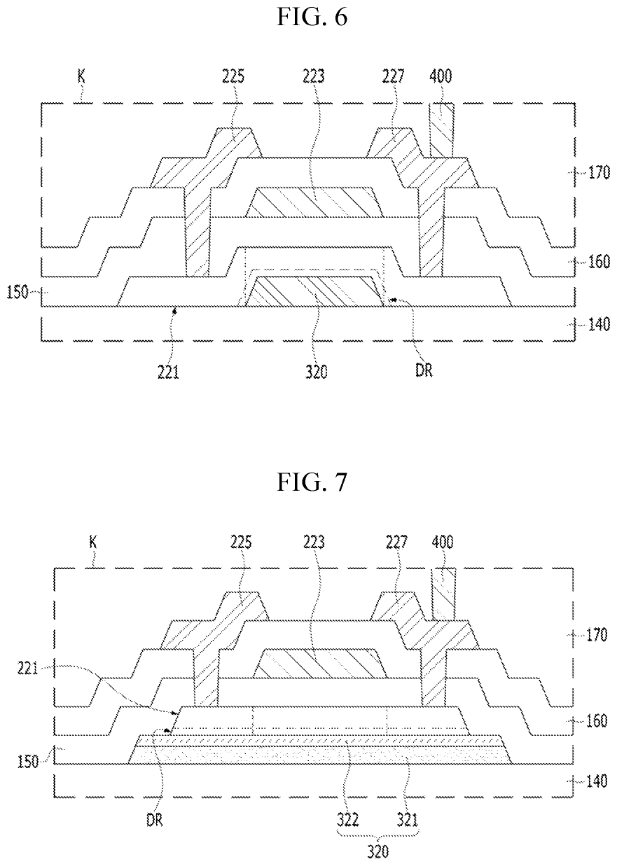

The display device according to the embodiment of the present disclosure has been described as being configured such that the second conductive pattern 320 in each pixel area PA has a larger size than the second semiconductor pattern 221 in the corresponding pixel area PA. However, in a display device according to another embodiment of the present disclosure, the second conductive pattern 320 in each pixel area PA may overlap a portion of the second semiconductor pattern 221 located in the corresponding pixel area PA. For example, as shown in FIG. 6, in the display device according to the other embodiment of the present disclosure, an edge of the second semiconductor pattern 221 located in each pixel area PA may be located outside the second conductive pattern 320 located in the corresponding pixel area PA. The second channel region of the second semiconductor pattern 221 located in each pixel area PA may be located on the second conductive pattern 320 in the corresponding pixel area PA. Each of the second source region and the second drain region of the second semiconductor pattern 221 located in each pixel area PA may include a region located outside the second conductive pattern 320 located in the corresponding pixel area PA. Accordingly, in the display device according to the other embodiment of the present disclosure, it may be possible to prevent the resistances of the second source region and the second drain region located in each pixel area PA from being increased by the depletion region DR formed between the second semiconductor pattern 221 and the second conductive pattern 320 in the corresponding pixel area PA. Therefore, in the display device according to the other embodiment of the present disclosure, image quality may be effectively improved.

The display device according to the embodiment of the present disclosure has been described as being configured such that the second conductive pattern 320 in each pixel area PA has a single-layer structure made of a metal. However, in a display device according to still another embodiment of the present disclosure, the second conductive pattern 320 in each pixel area PA may have a multilayer structure. For example, as shown in FIG. 7, in the display device according to the still another embodiment of the present disclosure, the second conductive pattern 320 in each pixel area PA may have a structure in which a first pattern layer 321 and a second pattern layer 322 are stacked one above another. The second pattern layer 322 may be electrically connected to the first pattern layer 321. For example, the second pattern layer 322 may be in direct contact with the upper surface of the first pattern layer 321 that is opposite the device substrate 100. The second pattern layer 322 may have a different composition ratio from the first pattern layer 321. The second pattern layer 322 may include the same metal as the first pattern layer 321. For example, the first pattern layer 321 may be a metal layer made of molybdenum (Mo), and the second pattern layer 322 may be a conductive metal oxide layer made of molybdenum oxide (MoOx).

The second semiconductor pattern 221 in each pixel area PA may be in direct contact with the second pattern layer 322 of the second conductive pattern 320 located in the corresponding pixel area PA. For example, the second pattern layer 322 in each pixel area PA may have a larger work function than the second semiconductor pattern 221 in the corresponding pixel area PA. Accordingly, in the display device according to the still another embodiment of the present disclosure, the second semiconductor pattern 221 in each pixel area PA may be in Schottky contact with the second pattern layer 322 of the second conductive pattern 320 located in the corresponding pixel area PA. That is, in the display device according to the still another embodiment of the present disclosure, the lower end portion of the second semiconductor pattern 221 located in each pixel area PA may include the depletion region DR formed by the second pattern layer 322 in the corresponding pixel area PA. The first pattern layer 321 may be thicker than the second pattern layer 322. Accordingly, in the display device according to the still another embodiment of the present disclosure, the second conductive pattern 320 may have sufficiently low resistance. Therefore, in the display device according to the still another embodiment of the present disclosure, the freedom of the configuration of the second conductive pattern 320 located in each pixel area PA may be improved.

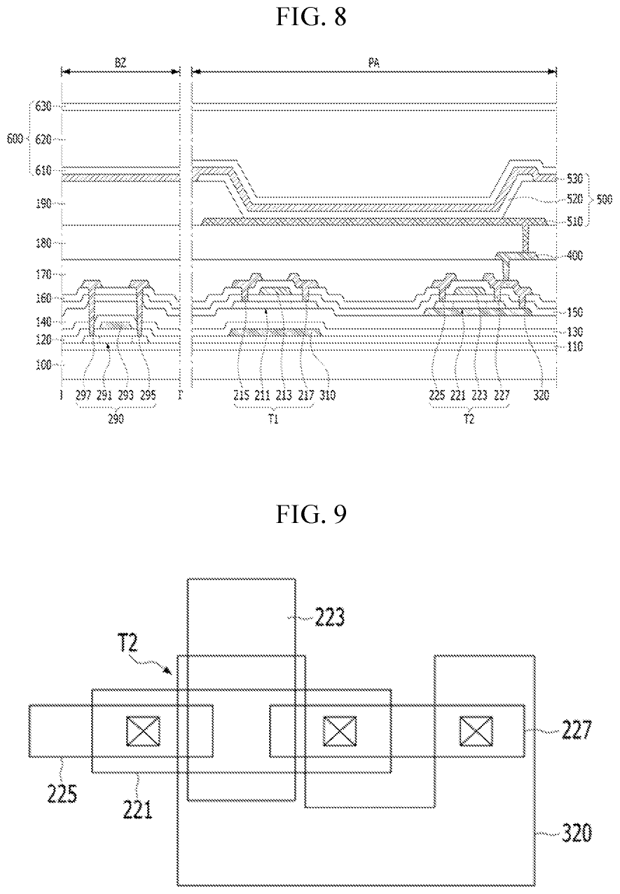

The display device according to the embodiment of the present disclosure has been described as being configured such that a constant voltage is applied to the second conductive pattern 320 in each pixel area PA. However, as shown in FIG. 8, in a display device according to yet another embodiment of the present disclosure, the second conductive pattern 320 in each pixel area PA may be electrically connected to the second source electrode 227 in the corresponding pixel area PA. That is, in the display device according to the yet another embodiment of the present disclosure, the voltage applied to the second conductive pattern 320 in each pixel area PA may correspond to the driving current generated by the second thin-film transistor T2 in the corresponding pixel area PA. The width of the depletion region DR formed between the second conductive pattern 320 and the second semiconductor pattern 221 in each pixel area PA may be proportional to a difference in work function between the corresponding second conductive pattern 320 and the corresponding second semiconductor pattern 221. That is, in the display device according to the yet another embodiment of the present disclosure, the configuration of each pixel driving circuit DC may be simplified without influencing the width of the depletion region DR formed in each pixel area PA. Accordingly, in the display device according to the yet another embodiment of the present disclosure, the freedom of the configuration of each pixel area PA may be improved.

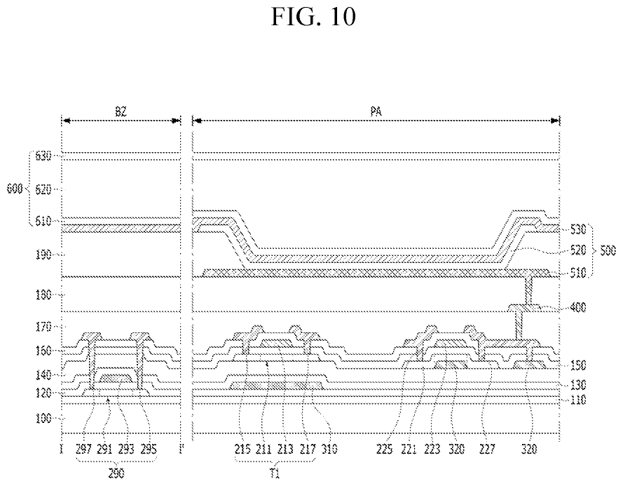

In the display device according to the yet another embodiment of the present disclosure, the second conductive pattern 320 electrically connected to the second source electrode 227 in each pixel area PA may be in direct contact with a portion of the second semiconductor pattern 221 located in the corresponding pixel area PA. For example, as shown in FIGS. 9 and 10, the second conductive pattern 320 that is in contact with the second channel region of the second semiconductor pattern 221 located in each pixel area PA is not disposed under the second source area and the second drain area in the corresponding pixel area PA. The second conductive pattern 320 in each pixel area PA may include a separate region located outside the second semiconductor pattern 221 located in the corresponding pixel area PA. The second source electrode 227 in each pixel area PA may be in direct contact with the second conductive pattern 320 in the corresponding pixel area PA at a position outside the second semiconductor pattern 221 located in the corresponding pixel area PA. Accordingly, in the display device according to the yet another embodiment of the present disclosure, the configuration of each pixel driving circuit may be simplified, and it may be possible to prevent the resistances of the second source region and the second drain region located in each pixel area PA from being increased by the depletion region formed on the lower end portion of the second semiconductor pattern 221 located in the corresponding pixel area PA.

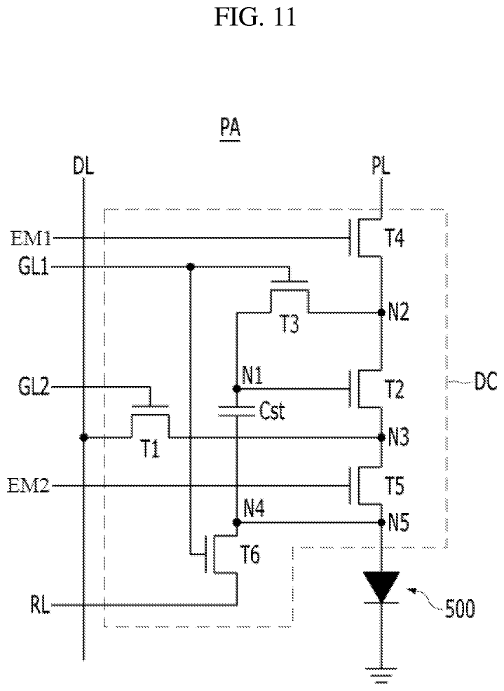

The display device according to the embodiment of the present disclosure has been described as being configured such that the pixel driving circuit DC in each pixel area PA includes two thin-film transistors T1 and T2. However, in a display device according to still yet another embodiment of the present disclosure, the pixel driving circuit DC in each pixel area PA may include one driving thin-film transistor and a plurality of switching thin-film transistors. For example, as shown in FIG. 11, in the display device according to the still yet another embodiment of the present disclosure, the pixel driving circuit DC in each pixel area PA may include six thin-film transistors T1, T2, T3, T4, T5, and T6 and one storage capacitor Cst. The first thin-film transistor T1 of each pixel driving circuit DC may be turned on in response to a second gate signal GL2 to supply the data signal to a third node N3. The third thin-film transistor T3 of each pixel driving circuit DC may be turned on in response to a first gate signal GL1 to diode-connect a first node N1 and a second node N2. The fourth thin-film transistor T4 of each pixel driving circuit DC may be turned on in response to a first emission control signal EM1 to supply a supply voltage applied through a power voltage supply line PL to the second node N2. The fifth thin-film transistor T5 of each pixel driving circuit DC may be turned on in response to a second emission control signal EM2 to electrically connect the third node N3 to a fifth node. The sixth thin-film transistor T6 of each pixel driving circuit DC may be turned on in response to the first gate signal GL1 to supply a reference voltage applied through a reference voltage supply line RL to the fourth node N4. The storage capacitor Cst of each pixel driving circuit DC may be electrically connected between the first node N1 and the fourth node N4. The second thin-film transistor T2 of each pixel driving circuit DC may generate a driving current corresponding to the data signal applied to the third node N3 using the supply voltage supplied to the second node N2. For example, the second thin-film transistor T2 of each pixel driving circuit DC may be a driving thin-film transistor. Accordingly, in the display device according to the still yet another embodiment of the present disclosure, the freedom of the configuration of each pixel driving circuit DC may be improved.

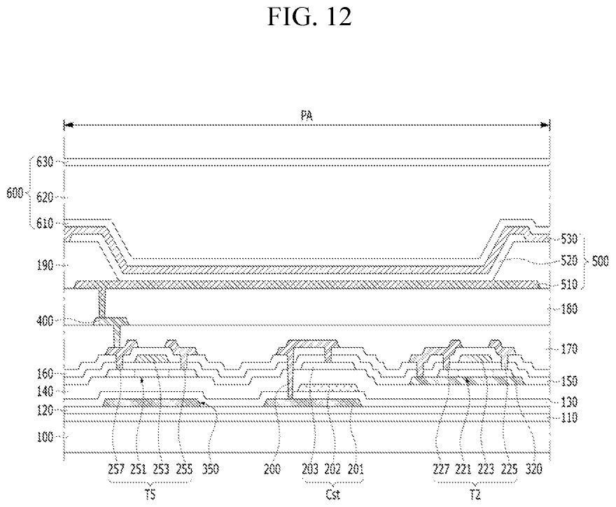

The display device according to the embodiment of the present disclosure has been described as being configured such that the storage capacitor Cst in each pixel area PA is formed simultaneously with formation of the first thin-film transistor T1 and the second thin-film transistor T2 in the corresponding pixel area PA. However, in a display device according to a further embodiment of the present disclosure, the storage capacitor Cst in each pixel area PA may be formed on a different layer from the thin-film transistors T1 and T2 in the corresponding pixel area PA. For example, as shown in FIGS. 11 and 12, in the display device according to the further embodiment of the present disclosure, the storage capacitor Cst located in each pixel area PA may have a structure in which a first capacitor electrode 201 and a second capacitor electrode 202 are stacked one above another, the first capacitor electrode 201 may be located between the lower gate insulating layer 120 and the lower interlayer insulating layer 130 in the corresponding pixel area PA, and the second capacitor electrode 202 may be located between the lower interlayer insulating layer 130 and the upper buffer layer 140 in the corresponding pixel area PA. Accordingly, in the display device according to the further embodiment of the present disclosure, the freedom of the configuration of the storage capacitor Cst located in each pixel area PA may be improved.

In the display device according to the further embodiment of the present disclosure, the storage capacitor Cst in each pixel area PA may further include a third capacitor electrode 203, which is located between the upper buffer layer 140 and the upper gate insulating layer 150 in the corresponding pixel area PA. The third capacitor electrode 203 may include a conductorized region of an oxide semiconductor. For example, the third capacitor electrode 203 in each pixel area PA may be formed simultaneously with formation of the second semiconductor pattern 221 in the corresponding pixel area PA. In each pixel area PA, the third capacitor electrode 203 may be electrically connected to the first capacitor electrode 201 via a capacitor connection electrode 200. Accordingly, in the display device according to the further embodiment of the present disclosure, the capacitance of the storage capacitor Cst located in each pixel area PA may be increased. Therefore, in the display device according to the further embodiment of the present disclosure, the freedom of the configuration of each pixel driving circuit may be improved.

In the display device according to the further embodiment of the present disclosure, at least one thin-film transistor may be disposed between the second thin-film transistor T2 and the light-emitting device 500 in each pixel area PA. For example, as shown in FIGS. 11 and 12, in the display device according to the further embodiment of the present disclosure, the driving current generated by the second thin-film transistor T2 in each pixel area PA may be supplied to the light-emitting device 500 in the corresponding pixel area PA by the fifth thin-film transistor T5 in the corresponding pixel area PA. The intermediate electrode 400 in each pixel area PA may pass through the first planarization layer 170 and may be in direct contact with a fifth source electrode 257 of the fifth thin-film transistor T5 located in the corresponding pixel area PA, and the first electrode 510 in each pixel area PA may pass through the second planarization layer 180 and may be in direct contact with the intermediate electrode 400 in the corresponding pixel area PA. A fifth semiconductor pattern 251 of the fifth thin-film transistor T5 may include an oxide semiconductor. For example, in the display device according to the further embodiment of the present disclosure, a fifth conductive pattern 350 may be located between the device substrate 100 and the fifth semiconductor pattern 251 in each pixel area PA. The fifth conductive pattern 350 may be located on a different layer from the second conductive pattern 320. For example, the fifth conductive pattern 350 may be located between the lower gate insulating layer 120 and the lower interlayer insulating layer 130. Accordingly, in the display device according to the further embodiment of the present disclosure, the freedom of the configuration of each pixel area PA may be improved.

As is apparent from the above description, the display device according to the present disclosure may include a conductive pattern, a light-emitting device, and a pixel driving circuit located in a pixel area of a device substrate. The pixel driving circuit electrically connected to the light-emitting device may include a driving semiconductor pattern located on the conductive pattern, the conductive pattern that is in contact with the driving semiconductor pattern may include a metal, and the conductive pattern may have a larger work function than the driving semiconductor pattern. That is, in the display device according to the present disclosure, the driving semiconductor pattern may be in Schottky contact with the conductive pattern. Accordingly, in the display device according to the present disclosure, it may be possible to increase an S-factor of a driving thin-film transistor including the driving semiconductor pattern without changing the thickness of an upper gate insulating layer covering the driving semiconductor pattern. Therefore, in the display device according to the present disclosure, occurrence of mura at low grayscale may be minimized or prevented without deterioration in brightness thereof. In addition, in the display device according to the present disclosure, low-power driving may be realized, whereby power consumption may be reduced.

Those skilled in the art will understand that various modification and alternations are possible from the above description without departing from the technical idea of the present disclosure. Consequently, the technical scope of the present disclosure is defined by the appended claims, not by the detailed description of the present disclosure.

What is claimed is:

1. A display device comprising:
a pixel driving circuit located on a device substrate, the pixel driving circuit comprising a driving thin-film transistor;
a conductive pattern located between the device substrate and the driving thin-film transistor, the conductive pattern comprising a metal; and
a light-emitting device located on the device substrate and electrically connected to the driving thin-film transistor,
wherein the driving thin-film transistor comprises a driving semiconductor pattern made of an oxide semiconductor,
wherein the driving semiconductor pattern is in contact with an upper surface of the conductive pattern, the upper surface being opposite the device substrate, and
wherein the metal of the conductive pattern has a larger work function than the oxide semiconductor of the driving semiconductor pattern.

2. The display device according to claim 1, wherein the driving semiconductor pattern comprises a rear portion located adjacent to the conductive pattern, and the rear portion comprises a depletion region.

3. The display device according to claim 1, wherein the conductive pattern is electrically connected to a driving source electrode of the driving thin-film transistor.

4. The display device according to claim 3, wherein the conductive pattern comprises a region located outside the driving semiconductor pattern so as not to overlap with the driving semiconductor pattern, and
wherein the driving source electrode is in contact with the conductive pattern at the region located outside the driving semiconductor pattern.

5. The display device according to claim 1, wherein the conductive pattern comprises a first pattern layer and a second pattern layer located on the first pattern layer,
wherein the driving semiconductor pattern is in contact with the second pattern layer, and
wherein the second pattern layer has a larger work function than the driving semiconductor pattern.

6. The display device according to claim 5, wherein the second pattern layer is made of a conductive metal oxide.

7. The display device according to claim 6, wherein the first pattern layer comprises a same metal as the second pattern layer.

8. The display device according to claim 1, wherein the conductive pattern comprises one of copper, molybdenum, nickel, cobalt, and platinum.

9. The display device according to claim 1, wherein the conductive pattern overlaps a first portion of the driving semiconductor pattern and does not overlap a second portion of the driving semiconductor pattern.

10. The display device according to claim 9, wherein the driving semiconductor pattern comprises a channel region overlapping with the conductive pattern.

11. A display device comprising:
a first conductive pattern located on a device substrate;
an upper buffer layer located on the device substrate to cover the first conductive pattern;
a second conductive pattern located on the upper buffer layer, the second conductive pattern comprising a metal;
a pixel driving circuit located on the device substrate, the pixel driving circuit comprising a first thin-film transistor located on the first conductive pattern and a second thin-film transistor located on the second conductive pattern; and
a light-emitting device electrically connected to the second thin-film transistor,
wherein the second thin-film transistor comprises a semiconductor pattern made of an oxide semiconductor, and
wherein the semiconductor pattern of the second thin-film transistor is in Schottky contact with the second conductive pattern.

12. The display device according to claim 11, wherein the second conductive pattern is electrically connected to a source electrode of the second thin-film transistor.

13. The display device according to claim 11, wherein the first thin-film transistor comprises a semiconductor pattern located on a same layer as the second conductive pattern.

14. The display device according to claim 13, wherein the semiconductor pattern of the first thin-film transistor comprises a same material as the semiconductor pattern of the second thin-film transistor.

15. The display device according to claim 13, further comprising:
an upper gate insulating layer located on the upper buffer layer,
wherein the upper gate insulating layer covers the semiconductor pattern of the first thin-film transistor and the semiconductor pattern of the second thin-film transistor,
wherein each of the first thin-film transistor and the second thin-film transistor comprises a gate electrode located on the upper gate insulating layer, and
wherein the gate electrode of the second thin-film transistor is located on a same layer as the gate electrode of the first thin-film transistor.

16. A thin film transistor for driving a light-emitting element of a display device, the thin film transistor comprising:
an oxide semiconductor pattern including oxide semiconductor material;
a gate insulation layer disposed on a first side of the oxide semiconductor pattern;
a gate electrode disposed on the gate insulation layer;
a first electrode electrically connected to the oxide semiconductor pattern;
a second electrode electrically connected to the oxide semiconductor pattern, the second electrode electrically connected to the light-emitting element such that the thin film transistor drives current through the light-emitting element;
a conductive pattern disposed directly on and in contact with a second side of the oxide semiconductor pattern, the conductive pattern having a first work function greater than a second work function of the oxide semiconductor pattern.

17. The thin film transistor of claim 16, wherein the conductive pattern is electrically coupled to a DC voltage or the second electrode.

18. The thin film transistor of claim 16, wherein:
the oxide semiconductor pattern includes a source region, a drain region, and a channel region between the source region and the drain region, the source region and the drain region including the oxide semiconductor material doped with a dopant, and the channel region including the oxide semiconductor material free of the dopant,
the conductive pattern extends shorter than edges of the oxide semiconductor region, and
the conductive pattern overlaps with the channel region but does not overlap with the source region or the drain region.

19. The thin film transistor of claim 18,
wherein the conductive pattern extends shorter than edges of the oxide semiconductor region; and
wherein the oxide semiconductor region has stepped shapes.

20. The thin film transistor of claim 16, wherein the conductive pattern overlaps with the entire oxide semiconductor pattern and extends beyond edges of the oxide semiconductor pattern.

21. The thin film transistor of claim 16, further comprising another conductive pattern disposed beyond edges of the oxide semiconductor pattern, the source electrode electrically connected to the another conductive pattern.

22. The thin film transistor of claim 16,
wherein the conductive pattern comprises a first conductive pattern layer and a second conductive pattern layer disposed on the first conductive pattern layer,
wherein the oxide semiconductor pattern is in direct contact with the second conductive pattern layer, and
wherein the second conductive pattern layer has the first work function greater than the second work function of the oxide semiconductor pattern.

23. The thin film transistor of claim 22, wherein the second conductive pattern layer comprises a conductive metal oxide.

24. The thin film transistor of claim 16, wherein the conductive pattern comprises one of copper, molybdenum, nickel, cobalt, and platinum.
